(19) United States
(12) Patent Application Publication
(10) Pub. No.: US 2025/0157801 A1
(43) Pub. Date: May 15, 2025

(54) SUB-MILLISECOND OPTICAL DETECTION OF PULSED PLASMA PROCESSES

(71) Applicant: Tokyo Electron Limited, Tokyo (JP)

(72) Inventors: Francisco Machuca, Fremont, CA (US); Joel Ng, Fremont, CA (US); Mihail Mihaylov, Fremont, CA (US); Xinkang Tian, Fremont, CA (US)

(21) Appl. No.: 18/505,810

(22) Filed: Nov. 9, 2023

(51) Int. Cl. H01J 37/32

(52) U.S. Cl. CPC H01J 37/32972; H01J 37/32146; H01J 37/32963

(57) ABSTRACT

An optical emission spectroscopy (OES) detection device includes an optical collector configured to be optically coupled to a plasma in a plasma processing apparatus, an adjustable wavelength filter optically coupled to the optical collector, and a photodetector optically coupled to the adjustable wavelength filter. The optical collector receives an optical signal from the plasma. The adjustable wavelength filter is configured to automatically adjust a passband of the adjustable wavelength filter to include a selected wavelength in response to receiving a wavelength selection signal, and allow a filtered portion of the optical signal to pass through while excluding a remaining portion of the optical signal. The filtered portion includes the selected wavelength. The photodetector is configured to generate an OES measurement in response to detecting the filtered portion of the optical signal with a response time that is less than one millisecond.

### TECHNICAL FIELD

The present invention relates generally to optical detection systems and methods for plasma processes, and, in particular embodiments, to a systems and method for sub-millisecond optical detection of pulsed plasma processes.

### BACKGROUND

Optical emission spectroscopy (OES) and thin film thickness monitoring is used for endpoint detection in plasma etch and plasma deposition systems, during film removal and film growth respectively. Traditional plasma OES is performed by coupling light from a plasma vacuum chamber out through a vacuum barrier via a transmissive view port and/or fiber coupling system. Thereafter, the signal is guided into a grating spectrometer for spectral analysis or thin film thickness determination; whose feature extraction over time can obviate a process endpoint.

Many spectrometers are limited to 1 ms to 100 ms time resolution of signals or have limited detection for temporal profiling. Because of temporal profiling limitations, plasma process tools today use a proxy plasma residence time signature 100 times to 10,000 times longer than needed to observe the direct reactant and byproduct evolution from or to a wafer's surface. As a result, future nodes utilizing this fingerprint or proxy signal in plasma processing will be challenged as complex 3D film stacks are constructed by additive and subtractive plasma processing requiring sub-nanometer thickness control. Examples of fast dynamic chemical changes during a pulsing scheme between plasma source power and wafer bias include shifts in concentration and temperature of species, such as ions, electrons, and radicals that are related to the pulse period (e.g., species lifetime may be 10's of microseconds while the pulse period is in the range of a millisecond). In some cases, one or more plasma properties must reach certain thresholds (e.g., a certain elevated electron temperature) to allow OES measurements to takes place. These plasma properties may also vary on timescales much faster than the pulse period.

For example, in some cases, using etching as an example, the material is completely removed using a proxy signal, or the precision to tolerance ratio of <10% for a good metrology cannot be met making the plasma etch process unreliable. Additionally, state-of-the-art modes to control the reactive ionized species in a plasma require fast pulsing schemes of both source power and wafer bias (e.g., synchronous, antisynchronous, or arbitrary pulse timing utilizing an offset between source and bias). For such fast pulsing schemes, detection limits obtained using the combination of fine time resolution and temporal profiling that are required to effectively resolve the energized precursors during their reactive state and during their purge/removal is in the range of 100's of nanoseconds to 100's of microseconds. For example, an active species generated during the early ramp of wafer bias, may require sub-millisecond time resolution to extract the relative concentration of active etch species to background reference species.

Therefore, sensors that can extend the detection range to below millisecond time resolution for more accurate observation of reactive species and plasma dynamics are desirable.

### SUMMARY

In accordance with an embodiment of the invention, an optical emission spectroscopy (OES) detection device includes an optical collector configured to be optically coupled to a plasma in a plasma processing apparatus and an adjustable wavelength filter optically coupled to the optical collector. The optical collector receives an optical signal from the plasma. The adjustable wavelength filter is configured to automatically adjust a passband of the adjustable wavelength filter to include a selected wavelength in response to receiving a wavelength selection signal, and allow a filtered portion of the optical signal to pass through while excluding a remaining portion of the optical signal. The filtered portion includes the selected wavelength. The OES detection device further includes a photodiode optically coupled to the adjustable wavelength filter. The photodiode is configured to generate an electric current as an OES measurement in response to detecting the filtered portion of the optical signal. The photodiode has an active area diameter that is less than about one millimeter.

In accordance with another embodiment of the invention, a pulsed plasma OES system includes a pulsed plasma processing apparatus that includes a plasma processing chamber and a source power (SP) coupling element configured to generate a plasma contained by the plasma processing chamber. The pulsed plasma OES system further includes an SP control path electrically coupled to the SP coupling element and configured to supply a sequence of SP pulses to the SP coupling element to generate the plasma, and an OES detection device optically coupled to the plasma. The OES detection device includes an adjustable wavelength filter and a photodetector. A control and data acquisition circuit is also included in the pulsed plasma OES system and is electrically coupled to the adjustable wavelength filter and the photodetector. The control and data acquisition circuit is configured to adjust a passband of the adjustable wavelength filter to a selected wavelength using a wavelength selection signal, and to cause the photodetector to collect a series of OES measurements of the plasma. The series of OES measurements has a temporal resolution less than a millisecond so that multiple OES measurements of the series are collected for each SP pulse of the sequence.

In accordance with still another embodiment of the invention, a method of collecting OES data of a pulsed plasma process includes selecting a first wavelength for an adjustable wavelength filter of an OES detection device optically coupled to a plasma processing chamber of a plasma processing apparatus configured to contain a plasma for the pulsed plasma process, and collecting a series of OES measurements of the plasma through the adjustable wavelength filter in response to the OES detection device receiving a synchronization signal corresponding to a sequence of source power pulses that are applied to the plasma processing chamber to generate the plasma. The series of OES measurements includes a temporal resolution less than a millisecond so that multiple OES measurements of the series are collected for each source power pulse of the sequence.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates an example pulsed plasma optical emission spectroscopy (OES) system that includes a sub-millisecond OES detection device optically coupled to a pulsed plasma processing apparatus in accordance with embodiments of the invention;

FIG. 2 illustrates an example timing diagram for a sub-millisecond OES detection device configured to acquire OES data from a pulsed plasma OES system that pulses source power during a plasma-on cycle in accordance with embodiments of the invention;

FIG. 3 illustrates another example timing diagram for a sub-millisecond OES detection device configured to acquire OES data from a pulsed plasma OES system that pulses both source power and bias power during a plasma-on cycle in accordance with embodiments of the invention;

FIG. 4 illustrates example optics of a sub-millisecond OES detection device that includes a single adjustable wavelength optical path where the optical path includes a Fabry-Pérot interferometer (FPI) and a photodiode in accordance with embodiments of the invention;

FIG. 5 illustrates example optics of a sub-millisecond OES detection device that includes multiple adjustable wavelength optical paths where each optical path includes an FPI and a photodiode in accordance with embodiments of the invention; and

FIG. 6 illustrates a method of collecting OES data of a pulsed plasma process in accordance with embodiments of the invention.

Corresponding numerals and symbols in the different figures generally refer to corresponding parts unless otherwise indicated. The figures are drawn to clearly illustrate the relevant aspects of the embodiments and are not necessarily drawn to scale. The edges of features drawn in the figures do not necessarily indicate the termination of the extent of the feature.

### DETAILED DESCRIPTION OF ILLUSTRATIVE EMBODIMENTS

The making and using of various embodiments are discussed in detail below. It should be appreciated, however, that the various embodiments described herein are applicable in a wide variety of specific contexts. The specific embodiments discussed are merely illustrative of specific ways to make and use various embodiments, and should not be construed in a limited scope. Unless specified otherwise, the expressions “around”, “approximately”, and “substantially” signify within 10%, and preferably within 5% of the given value or, such as in the case of substantially zero, less than 10% and preferably less than 5% of a comparable quantity.

The embodiments described herein relate to optical emission spectroscopy (OES) system and methods that are configured to acquire OES information of a plasma process using a fast temporal profiling sensor (i.e., a sub-millisecond OES detection device). That is, the sub-millisecond OES detection device has a temporal resolution extending below millisecond time resolution (e.g., down to 100's of nanoseconds, or even to 10's of nanoseconds). This may beneficially allow observation of various reactive species as well as plasma dynamics (such as sheath bending leading to center-to-edge wafer non-uniformities, plasma chamber instabilities, or incorrect synchronization of source power to wafer bias causing incorrect active species etch duration during cyclic etch, etc.).

In various embodiments, an OES detection device includes an adjustable wavelength filter (e.g., a Fabry-Pérot interferometer (FPI)) and a photodetector (e.g., a photodiode) optically coupled to the adjustable wavelength filter. The adjustable wavelength filter is configured to receive an optical signal from a plasma in a plasma processing apparatus. A passband of the adjustable wavelength filter can be automatically adjusted to include a selected wavelength in response to receiving a wavelength selection signal. The adjustable wavelength filter is configured to allow the filtered portion of the optical signal that includes the selected wavelength to pass through while excluding the remaining portion of the optical signal. The photodetector is configured to generate an electric current as an OES measurement in response to detecting the filtered portion of the optical signal.

The photodetector may be configured to have a response time that is less than one millisecond. In various embodiments, the photodetector has a small active area (e.g., a photodiode with an active area diameter less than about one millimeter), which may increase the response time of the photodetector compared to photodetectors with larger active areas. The OES detection device may also include an optical collector configured to be optically coupled to the plasma to collect the optical signal from the plasma and provide the optical signal to the adjustable wavelength filter (e.g., configured to adjust the collection angles to the optimal emission angles to maximize capturing the etch chemistry of interest's fingerprint, or maximize the etendue (solid angle to emission object aerial size product), for example, through an optical window in a plasma processing chamber of the plasma processing apparatus).

The OES detection device may perform various methods of collecting OES data of the plasma process (e.g., a pulsed plasma process using synchronous, antisynchronous, or arbitrary pulse timing, such as with phase locked off-time). In various embodiments, a method of collecting OES data of a plasma process includes selecting a wavelength for the adjustable wavelength filter and collecting a series of OES measurements of the plasma through the adjustable wavelength filter. The series of OES measurements have a temporal resolution less than a millisecond (i.e., sub-millisecond). For example, the method may be used to collect OES data of a pulsed plasma process (e.g., in synchronization with or offset relative to a pulse). The series of OES measurements may be collected in response to the OES detection device receiving a synchronization signal corresponding to a sequence of source power pulses applied to a plasma processing chamber to generate the plasma.

The temporal resolution may be less than a millisecond may so that multiple OES measurements of the series are collected for each source power pulse of the sequence. In some cases the frequency of measurement and/or temporal resolution may be selected in order to maximize the collection signal in the window of time when the reactive species is maximal within the “on” pulse. In the latter case, this can maximize the correlation to an endpoint signature whilst time trending the OES signal. For example, the sensitivity may be enhanced by (e.g., by 2×, or more) when the measurement period is synchronized within each similar portion of the excitation period for all the series of plasma pulses (e.g., a steeper slope indicative of increased sensitivity for catching an endpoint, such as in plasma etching, may be achieved by specifically measuring regions of interest during each pulse rather than the conventional approach of averaging the entire pulse). That is, without fast time synchrony, the OES measurements may be susceptible to averaging out or washing out the edge for endpoint detection.

The OES detection device may be included in plasma processing system, such as a pulsed plasma processing system, to provide OES capabilities. For example, the OES system may include a plasma processing apparatus and a control and data acquisition circuit electrically coupled to the adjustable wavelength filter and the photodetector of the OES detection device. The control and data acquisition circuit may be configured to adjust a passband of the adjustable wavelength filter to the selected wavelength using the wavelength selection signal and to cause the photodetector to collect the series of OES measurements of the plasma. When the OES system is a pulsed plasma OES system, a source power control path may be included that is electrically coupled to a source power coupling element of the plasma processing apparatus. The source power control path may be configured to supply a sequence of source power pulses to the source power coupling element to generate the plasma.

In various embodiments, the invention provides systems, devices, and methods for an ultrafast response time (i.e., less than a millisecond) OES detection. For example, OES detection devices may include one or more photodetectors (such as a photodiode) with fast response times (e.g., sub-nanosecond rise/fall times for a small-area photodiode, such as with an active area diameter <1 mm, may have short rise/fall times, e.g., <0.5 ns, down to 100 ps, such as when the active area diameter is in the range of about 100 μm to about 1 mm, or even lower). One or more included adjustable wavelength filters (such as an FPI, double grating, etc.) may provide monochromatic or near monochromatic light to the photodetectors. For example, a desired narrow passband (e.g., 0.1 nm to 4 nm) may be selected to be used for collecting OES measurements for each of the adjustable wavelength filters. Because of the temporal resolution less than a millisecond (e.g., as low as 100 ns, 10 ns, or higher resolution), 100's to 1000's of measurements can advantageously be made for each source power on/off cycle of a pulsed plasma process. Additionally, by using an out-of-synchrony measurement window, a plasma-off diagnostic may also be implemented asynchronously to monitor when plasma is extinguishing improperly, or to detect arcing events throughout the measurement cycle (e.g., when plasma is normally off).

The invention may provide various advantages over conventional OES spectrometers. In comparison to conventional OES spectrometers, embodiment OES detection devices may provide the advantage of larger throughput by collecting significant etendue without the illumination losses in irradiance typical of conventional OES spectrometers utilizing narrow slits that set resolution and a low efficiency grating. For example, conventional OES spectrometers may have roughly 10 times to 100 times lower throughput than embodiments of the invention.

Embodiment OES devices may also advantageously have fast rise times and fall times (such as less than 500 ps, as short as 100 ps, or even shorter) enabling improved speed of detection. Further, the embodiment OES devices may have the benefit of high responsivity in the wavelength ranges of interest (e.g., 190 nm to 1100 nm). In contrast, conventional OES spectrometers are limited by integration times and/or ADC response times that are in the range of 1 ms to 100 ms.

A further possible advantage of the embodiment OES detection devices may be the ability of selecting one or more wavelengths of light for repeatable measurements at a high sampling rate that provides 100's to 1000's of time slices per plasma cycle (source power on/off in the case of a pulsed plasma process) over the full length of the plasma measurement that can last 100's of seconds. For example, embodiments herein provide systems, devices and methods to advantageously monitor and detect process endpoints in synchrony with a plasma processing tool (e.g., a pulsed plasma processing apparatus). Moreover, the miniaturization of sensor and the collection optics of the embodiment OES detection devices may have the benefit of enabling unique arrays of devices for the purpose of simultaneously measuring a multiplicity of wavelengths (including wavelengths commonly of interest in OES analysis of a plasma process, for example).

The invention may also afford several advantages related to applications of the embodiment OES detection devices. For example, the improved temporal profiling or time resolution (i.e., less than a millisecond, preferably less than about 100 μs, as down to 100 ns, 10 ns, and even higher resolution) may provide the novel advantage of allowing the direct OES measurement of chemical reactions occurring in the plasma during a plasma process (e.g., at timescales ranging from 100's of microseconds to 100's of nanoseconds, or lower). The embodiment OES detection devices may beneficially collect OES data in during a plasma process (e.g., in synchrony with a power cycle of a pulsed plasma process) while operating under closed loop control to extract and monitor features.

Further, embodiment OES detection devices may also provide the capability of probing in synchrony with pulsed plasma processes, even when the source power and wafer bias are out of phase, allowing direct OES measurement of active reacting species. For example, embodiment OES detection devices may provide time slices corresponding to 100's or 1000's of sample points for the purpose of measuring precisely in time reactive species in a plasma at the surface of a substrate (e.g., wafer). Conventionally unresolvable phenomena that may be advantageously resolved using the embodiments disclosed here include (1) discharge phenomena at timescales <0.9 μs, (2) plasma recombination events at timescales ranging from about 0.1 μs to about 100 μs, and (3) plasma chemistry such as chemical reactions involving radicals at timescales on the order of 10 μs, chemical reactions involving neutral species at timescales on the order of 1 ms, and species diffusion at timescales ranging from about 10 ms to about 100 ms.

Fine-grained OES data may allow monitoring of the concentration of active reacting species as it falls off, thereby increasing the detectability and accuracy of endpoint detection of the plasma process (e.g., even when the open area ratio in etch is small). Additionally, the residence time of the active species (i.e., how long the active species remain at the substrate before being purged away) can be directly measured. For example, this may enable the determination of an off-duty cycle (i.e., percentage of a cycle in which no source and/or bias power is provided) that is sufficient to reach a desired degree of evacuation (such as 1/e, 1/2e, 1/n*e, where n is an integer).

Another potential advantage of the embodiment OES detection devices is the ability to measure multiple wavelengths simultaneously with time resolution less than a millisecond (e.g., in the range of about 100 μs to about 100 ns, or lower). A high signal-to-noise ratio (SNR) may also advantageously be maintained, such as because of the improved etendue and/or device throughput, or synchrony with specific regions of each pulse where the signal is present.

Yet another possible benefit of the embodiment OES detection devices is the capability of collecting OES measurements only at desired portions of a pulse cycle (e.g., only when the source power is high or on, only when the bias power is high or on, when both or either are on, or at any desired interval during the pulse cycle). For example, a trigger may be used (e.g., a synchronization signal) periodically (such as every pulse cycle) to facilitate effective lock-in detection. In one particular example, the plasma processing apparatus may change the plasma from high source power to low source power, and OES measurements can be collected during the duty cycle when the power is high, which may advantageously lead to improvements of in the SNR (e.g., because the primary signal is in proportion to the excitation power of the plasma).

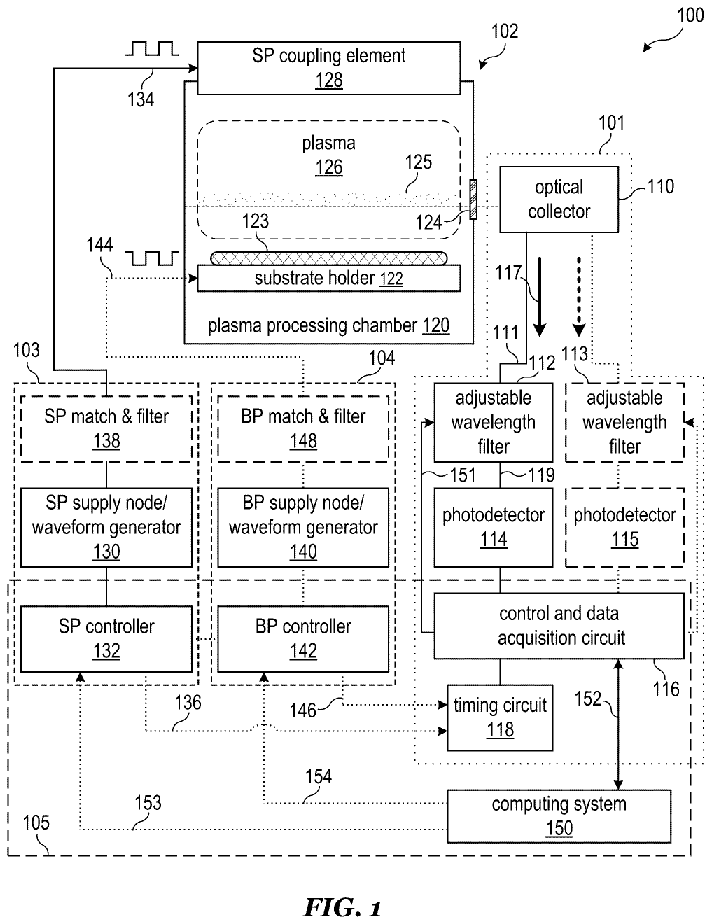

FIG. 1 illustrates an example pulsed plasma optical emission spectroscopy OES system that includes a sub-millisecond OES detection device optically coupled to a pulsed plasma processing apparatus in accordance with embodiments of the invention.

Referring to FIG. 1, a pulsed plasma OES system 100 includes an OES detection device 101 optically coupled to a plasma processing apparatus 102 (e.g., using an optical window 124 such as a vacuum viewport, for example). The pulsed plasma OES system 100 is configured to be used to perform a plasma process (a pulsed plasma process in this case) using plasma processing apparatus 102 during which OES measurements are collected. For example, the plasma processing apparatus 102 may include a substrate holder 122 (e.g., an electrostatic chuck, etc.) disposed in a plasma processing chamber 120 and configured to support a substrate 123 (e.g., any suitable substrate such as a wafer) to be processed by a plasma 126. The plasma processing apparatus 102 is a pulsed plasma apparatus in some embodiments (as shown).

The OES detection device 101 is optically coupled to the plasma 126 such that the OES detection device 101 receives an optical signal 125 from the plasma 126. An optical path 117 of the OES detection device 101 includes an adjustable wavelength filter 112 and a photodetector 114. The OES detection device 101 may also include an optical collector 110 that is optically coupled to the adjustable wavelength filter 112 through upstream optics 111 configured to direct the optical signal 125 to the adjustable wavelength filter 112. That is, the optical collector 110 may be configured to be optically coupled to the plasma 126 and receive the optical signal 125 from the plasma 126. Similarly, the optical path 117 may also include downstream optics 119 optically coupling the adjustable wavelength filter 112 to the photodetector 114. For example, the optical collector 110 and the upstream optics 111 may include various components such as reflectors, lenses, apertures, splitters, fiber optics, and the like.

The adjustable wavelength filter 112 of the OES detection device 101 is configured to allow a filtered portion of the optical signal 125 (having wavelengths within a passband of the adjustable wavelength filter 112) to pass through the filter while the remaining portion of the optical signal 125 is excluded. The passband of the adjustable wavelength filter 112 is configured to be adjusted. For example, the adjustable wavelength filter 112 may be configured to automatically adjust a passband of the adjustable wavelength filter to include a selected wavelength in response to receiving a wavelength selection signal 151.

The passband of the adjustable wavelength filter 112 may be a single wavelength or a range of wavelengths. The adjustable wavelength filter 112 may be designed to have a narrow passband (e.g., in order to focus the OES measurements on a wavelength of interest, increase SNR, reduce processing time, etc.). For example, in various embodiments, the passband is less than about 4 nm, and between about 0.1 nm and about 4 nm in some embodiments. As a result, the narrow passband of the adjustable wavelength filter 112 allow monochromatic or nearly monochromatic light from the optical signal 125 to pass through to the photodetector 114.

The adjustable wavelength filter 112 may by implemented using various types of adjustable filters. In one embodiment, the adjustable wavelength filter 112 includes a Fabry-Pérot interferometer (FPI) with a tunable (i.e., adjustable) air gap. In some embodiments, the adjustable wavelength filter 112 includes abutting interference filters (e.g., two or more) such as optical gratings, or order sorting filters, and in both cases they may be transmissive or reflective. In one embodiment, the adjustable wavelength filter 112 includes a purely reflective filter with sharp cut-on and cut-off characteristics in the range of 200-450 nm range with OD of >3 outside the pass band. For example, in one embodiment the adjustable wavelength filter 112 includes a double grating configured to be adjusted relative to one another using linear motion. In another embodiment, the adjustable wavelength filter 112 includes a double grating configured to be adjusted relative to one another using rotational motion. The width of the passband of the adjustable wavelength filter 112 may also be adjustable, such as by including two or more order sorting filters in the adjustable wavelength filter 112 or by offsetting components such as filters (e.g., two or more offset FPIs) or apertures to exclude higher orders.

The photodetector 114 is configure to generate an electric current as an OES measurement in response to detecting the filtered portion of the optical signal 125. The photodetector 114 may be sensitive to a range of wavelengths spanning or from a portion of the optical region of the electromagnetic spectrum. In various embodiments, the photodetector 114 has responsivity in one or more of the visible (VIS), ultraviolet (UV), and infrared (IR) regions of the electromagnetic spectrum. For example, the photodetector 114 may have responsivity in the range of about 100 nm to about 1 mm, preferably about 280 nm to about 10 μm, preferably about 315 to about 1 μm.

The photodetector may be implemented using various types of photodetectors capable of being configured to have response times less than a millisecond (e.g., having rise and fall times of the generated electric current that are short, such as less than about a nanosecond, preferably less than 100 ps, or even shorter). For example, certain types of photodetectors, such as charge coupled device (CCD) sensors, CMOS image sensors (CIS), photomultiplier tube (PMT) sensors, etc., used in conventional OES spectrometers are not be capable of sub-millisecond response times. In various embodiments, the photodetector 114 comprises a photodiode, and is a small-area photodiode having an active area diameter less than about a millimeter in some embodiments (e.g., in the range of about 1 mm to about 100 μm, or smaller). Various types of photodiodes may be used in the photodetector 114, such as PIN photodiodes, avalanche photodiodes, and the like. In one embodiment, the photodetector 114 includes a single photodiode device (e.g., in order to reduce complexity and/or integration time), but more than one photodetection device may be included in the photodetector 114.

The pulsed plasma OES system 100 includes a control and data acquisition circuit 116 (e.g., as part of the OES detection device 101 or as a separate element of the pulsed plasma OES system 100). The control and data acquisition circuit 116 is electrically coupled to the adjustable wavelength filter 112 and the photodetector 114. That is, the control and data acquisition circuit 116 is configured to adjust the passband of the adjustable wavelength filter 112 to the selected wavelength using the wavelength selection signal 151. Additionally, the control and data acquisition circuit 116 is further configured to cause the photodetector 114 to collect a series of OES measurements of the plasma 126. The series of OES measurements has a temporal resolution less than a millisecond (preferably lower than about 100 μs, such as between about 100 μs and 100 ns, or even higher resolution). For example, the control and data acquisition circuit 116 may be configured to set the integration time of the photodetector 114 to a desired value (such as between about 2 μs and about 100 μs, for example).

Source power (SP) is applied to an SP coupling element 128 of the plasma processing apparatus 102 using a SP control path 103 electrically coupled to the SP coupling element 128 to generate the plasma 126 in a plasma processing chamber 120 (e.g., contained by the plasma processing chamber 120). Bias power (BP) may be applied to the substrate holder 122 using an optional BP control path 104. The bias power (e.g., a wafer bias) may create a potential difference between the substrate 123 and the plasma 126 that may be used to influence charged species of the plasma 126 during a plasma process (e.g., to accelerate ions/electrons towards or away from the substrate 123).

In the specific implementation of the pulsed plasma OES system 100 as a pulsed plasma OES system illustrated here, the SP control path 103 is configured to supply a sequence of SP pulses 134 to the SP coupling element 128 to generate the plasma 126. For example, the SP control path 103 may include an SP supply node/waveform generator 130 that is configured to supply source power (e.g., alternating current (AC) power such as radio frequency (RF) power) and modulate the source power to generate the sequence of SP pulses 134. An SP controller 132 may be configured to control the timing and parameters of the sequence of SP pulses 134. The series of OES measurements may have the temporal resolution less than a millisecond so that multiple OES measurements of the series are collected for each SP pulse of the sequence of SP pulses 134. An optional SP match & filter 138 may be included between the SP supply node/waveform generator 130 and the SP coupling element 128 (e.g., for ensuring efficient coupling of the source power to the plasma 126).

Similarly, when included, the optional BP control path 104 may be configured to supply a sequence of BP pulses 144 to the substrate holder 122. For example, the optional BP control path 104 may include a BP supply node/waveform generator 140 that is configured to supply bias power (e.g., RF bias power, direct current (DC) bias power, or a combination thereof) and modulate the bias power to generate the sequence of BP pulses 144. A BP controller 142 may be configured to control the timing and parameters of the sequence of BP pulses 144. An optional BP match & filter 148 may be included between the BP supply node/waveform generator 140 and the substrate holder 122 (again, to ensuring efficient coupling of the bias power to the substrate 123, for example).

The pulsed plasma OES system 100 also includes a control system 105 operationally coupled to the OES detection device 101 and the SP control path 103 (and to the optional BP control path 104, when included). The control system 105 is configured to provide control of both the plasma process and the acquisition of OES data. For example, the control system 105 may include the control and data acquisition circuit 116, the SP controller 132, and the BP controller 142. A timing circuit 118 may be included in the control system 105 (e.g., as part of the OES detection device 101, as shown). The timing circuit 118 is electrically coupled to the photodetector 114 (e.g., through the control and data acquisition circuit 116) and is configured to control the timing for the collection of the series of OES measurements, such as by ensuring locked-in synchrony with the plasma pulsing (SP or BP). For example, the timing circuit 118 may include various components such a flip flop, a clock generator circuit, such as within a microcontroller, FPGA, and the like.

The timing circuit 118 may be configured to generate a setup delay in response to receiving a synchronization signal from the plasma processing apparatus 102. The control and data acquisition circuit 116 may be configured to use the synchronization signal (e.g., directly or indirectly from the timing circuit 118) to cause the OES detection device 101 to collect the series of OES measurements during a selected portion of each power cycle of the sequence of SP pulses 134 during a selected portion of each power cycle of the sequence of BP pulses 144, or any desired portion of the pulsed plasma process.

The synchronization signal may take a variety of forms. In one embodiment, the synchronization signal is an SP trigger signal 136 sent from the SP control path 103 (such as by the SP controller 132) and corresponds to the timing of the sequence of SP pulses 134. In some embodiments, the SP trigger signal 136 corresponds directly to the sequence of SP pulses 134 (such as rising and/or falling edges) and in other embodiments the SP trigger signal 136 is a separate signal sent a predetermined amount of time prior to the sequence of SP pulses 134. Similarly, the synchronization signal may also be (or include) a BP trigger signal 146 sent from the optional BP control path 104 (such as by the BP controller 142) and correspond to the timing of the sequence of BP pulses 144.

The timing circuit 118 may be further configured to generate a clock signal and cause the OES detection device 101 to collect a series of OES measurements from the photodetector 114 (e.g., by triggering the control and data acquisition circuit 116) by switching the photodetector 114 off and on after the setup delay according to the clock signal (such as at the clock signal frequency). In various embodiments, the clock signal has a frequency greater than 1 kHz (to facilitate sub-millisecond temporal resolution, for example).

The control system 105 may also include a computing system 150 as part of the OES signal acquisition chain that is configured to send control signals to the control and data acquisition circuit 116, the SP controller 132, and the BP controller 142 (labelled as control and data signal 152, SP control signal 153, and BP control signal 154, respectively). The control and data acquisition circuit 116 may be configured to process, amplify, and digitize the series of OES measurements for output to computing system 150 (e.g., in real-time or near real-time). The computing system 150 may also be configured to log the OES data, define and extract features, and display the OES data. For example, the computing system 150 may include a graphical user interface allowing control and visualization of the OES data acquisition process.

The computing system 150 may be any suitable type of computing system, including a digital computer, microprocessor, microcontroller, field-programmable gate array (FPGA), or application-specific integrated circuit (ASIC), with any suitable instruction set, such a complex instruction set computer (CISC), reduced instruction set computer (RISC), real-time operating system (RTOS) computer, etc. The computing system 150 may include a processor and a computer-readable non-transitory memory storing a program, that, when executed by the processor, causes the processor to perform the methods of collecting OES data of a plasma process described herein. In some cases, the control and data acquisition circuit 116 may include a memory and processor configured to perform a portion of or all of the methods of collecting OES data of a plasma process.

The optical path 117 may be configured to correspond with a single selected wavelength (or wavelength range), by virtue of the adjustable wavelength filter 112. In various embodiments, additional adjustable wavelength optical paths may be included in the OES detection device 101. For example, each of the additional adjustable wavelength optical paths may include an optional additional adjustable wavelength filter 113 and an optional additional photodetector 115 (as shown). The additional adjustable wavelength optical paths may advantageously allow for simultaneous selection on multiple wavelengths of interest during collection of the series of OES measurements.

When the adjustable wavelength filter 112 includes a mirror (such as with the adjustable wavelength filter 112 comprises an FPI), the mirror reflectivity may be tunable (i.e., electronically adjustable). For example, tuning the mirror reflectivity may be used to enhance finesse, which may allow leverage of the tradeoff between transmission and the narrowness of the spectral bandwidth.

The selected wavelength (or wavelength range) of the adjustable wavelength filter 112 may be adjusted at high speeds in various embodiments. Additionally, the adjustable wavelength filter 112 may be adjusted while the series of OES measurements is being collected. For example, during OES acquisition, an oscillatory voltage may be applied to continuously adjust the adjustable wavelength filter 112 (e.g., to change the distance of the tunable air gap in an FPI). In this way, multiple color measurement using a single adjustable wavelength filter 112 may be enabled (such as when doing a survey scan over a wide range of wavelengths).

Although a linear voltage sweep to adjust the adjustable wavelength filter 112 is of course possible, the oscillatory may have the advantage of allowing the series of OES measurements to provide OES data for multiple wavelengths at high temporal resolution (e.g., sub-millisecond). In some cases, OES data may be collected as the adjustable wavelength filter 112 moves in one direction (e.g., the gap closes), and the OES data may be acquired on the flyback (opening). This may enhance the speed of a broad survey scan over many colors, for example.

In applications that adjust the adjustable wavelength filter 112 between multiple wavelengths during a scan, the acquisition speed of the series of OES measurements and the adjustment speed of the adjustable wavelength filter 112 must be faster to achieve the same temporal resolution (e.g., sub-millisecond temporal resolution). Given the fast response times discussed, the impact of sampling a relatively small selection of wavelengths with a single adjustable wavelength filter 112 may be small. For example, the adjustable wavelength filter 112 may be set to two or more color passbands while still making measurements with temporal resolution ranging from 100's of nanoseconds to 100's of microseconds. In various embodiments, the adjustable wavelength filter 112 may be adjusted using driving voltage frequencies greater than 10 kHz. The drive mechanism may include piezo configurations, such as a tube cylinders with piezo actuators in the case of FPIs.

In principle, the plasma processing apparatus 102 can pulse source power (and bias power) in phase, out of phase, or pulse solely the source power (with continuous wave (CW) bias power or no bias power, for example). During the OES measurement, taking the specific example of both pulsed source power and pulsed bias power during on/off cycles of the plasma 126, a synchronization trigger signal is received by the OES detection device 101 preparing for data acquisition using the pre-defined wavelength (e.g., gap) settings for each adjustable wavelength filter 112 (e.g., FPI). The correspondence from the physical position (e.g., gap size) to the selected wavelength is a calibration and may be stored in a known lookup table (LUT).

Data acquisition may be triggered by the OES detection device 101 (such as by the control and data acquisition circuit 116) and a set of integration windows are recorded with predefined time widths settable by the user (such as in the range of about 2 μs to about 100 μs, but any suitable integration time may be chosen). For each sampled time, the control and data acquisition circuit 116 may send a digitized form of the voltage representing the signal of interest for a given sensor channel. This digitized voltage may in turn be proportional to a given chemical species (reactant, by product, ions, neutrals, radicals, etc.). The digitized signal may then be sent to the computing system 150 for further processing and monitoring.

Using program instructions (e.g., PC software methods, RTOS, RISC, etc.) features that are extracted may be time-trended to identify when the concentration of a given reacting species and/or byproduct has hit a limiting threshold value signifying completion of the plasma process (or a stage of the plasma process). An advantage may be that averages of the sample points (e.g., 100's to 1000's) representing the chemical species with time resolution significantly shorter than one pulse on/off cycle may be assembled, yielding direct measurement of the chemical reactions for process control.

In summary, certain implementations of the photodetector 114 (such as a photodiode), may be triggered to turn on and measure in synchrony with a plasma tool trigger. The response time may be limited by the larger value of either the integration time or the analog-to-digital converter (ADC) conversion time and can be in the range of 100's of nanoseconds to 1 millisecond (or even lower, but having sufficient irradiance above the sensor noise floor may be a consideration). Hence, for a 10 kHz plasma pulse, and a 1 μs integration time for the sampling window of the photodetector 114, will have 250 samples in a single power on to off cycle for a 50% duty cycle from on to off. This may be recognized as a clear advantage in temporal profiling over the conventional OES spectrometers.

The plasma processing apparatus 102 may be any type of plasma processing apparatus configured to use the plasma 126 to process (e.g., modify, prepare, clean, etc.) the substrate 123. For example, the plasma processing apparatus 102 may be an etch tool, a deposition tool, a cleaning tool, plasma thinning or dicing tool, and the like. Additionally, the plasma processing apparatus 102 may be used for more than one type of plasma processing. The plasma 126 may be any type of plasma such as an inductively coupled plasma (ICP), capacitively coupled plasma (CCP), surface wave plasma (SWP), and others (where the implementation of the SP coupling element 128 may vary in order to generate plasma of a given type).

The optical signal 125 is illustrated as a light cylinder sampled from the plasma 126 to represent a possible region of the plasma 126 that is represented in the series of OES measurements. That is, initial light reaching the OES detection device 101 may in reality be more like a light cone, and the optical path 117 may include various components (such as in the optical collector 110) that filter and focus the light cone to create a pencil of light (i.e. a light cylinder) which is eventually sampled by the photodetector 114.

Optics may be included to modify the extent of the light cylinder. For example, a “digitally selecting slit” may effectively be created using the addition of a variable magnification optic (e.g., having an adjustable magnification range of 1×-8×). This may serve as an angular filter from the plasma processing chamber 120 to advantageously optimize the fraction of the signal of interest from background plasma removing in part a source of parasitic noise (i.e., enabling to narrow the acceptance cone to focus on byproduct signal above the wafer by having the plasma background fall off the detector as magnification is changed). Other mechanisms may also be included to sample different or larger areas of the plasma 126, such as gimbaled mirrors to adjust the light cylinder, multiple optical collectors positioned to sample a wide region of the plasma 126 (or specific regions of interest such as center, edge, etc.). Moreover, said gimbaled mirror may be configured to redirect light from a spatially defined zone above the wafer to simultaneously achieve temporal and spatial resolved OES.

One application of the pulsed plasma OES system 100 that may be particularly advantageous is endpoint detection (EPD) of the plasma process (e.g., a plasma process such as plasma etching or plasma deposition). EPD may be used to monitor the plasma process (in this case using the series of OES measurements) for an indication of an endpoint of the plasma process. The plasma processing apparatus 102 may then be instructed to terminate or change the plasma process in response to detecting the endpoint (e.g., by the computing system 150, the control and data acquisition circuit 116, or another controller). Additionally, with the addition of both the gimbaled mirror and the synchronous OES, the EPD may selectively be monitored for one or more locations above the wafer, such as reporting the EPD condition from center to edge of the wafer. For example, the latter is known to vary, and more judicious algorithms may be reached by leveraging knowledge of the center EPD difference with respect to the edge, or vice versa. In one embodiment, over etching may be utilized to accomplish complete etching center-to-edge across the full wafer, accounting for regions that are etching slower due to plasma chamber non-uniformities.

Some examples of plasma processes for which EPD can be use are plasma-enhanced chemical vapor deposition (PE-CVD), atomic layer deposition (ALD), reactive ion etching (RIE), atomic layer etching (ALE). For example, EPD can be used to detect that the material being etched has been cleared to an underlying layer. Depending on the types of materials being etched and the etch process parameters, changes in the OES data of the plasma 126 at or near an endpoint of the etch process may be subtle and undetectable using conventional OES spectrometers (e.g., because the relevant processes occur at timescales smaller than a millisecond). However, the sub-millisecond OES detection device 101 may have the advantage of detecting many processes of interest for endpoint detection and process health, such as discharge phenomena, plasma recombination, and plasma chemistry including radical reactions, neutral species reactions, and species diffusion.

It should be noted a variety of implementation configurations exist for the control system 105. For example, some or all of the controllers of the various subsystems and devices of the pulsed plasma OES system 100 may be included in the respective subsystem or device. For example, as shown, the control and data acquisition circuit 116 may be included as part of the OES detection device 101, the SP controller 132 may be included as part of the SP control path 103, and so on. Further, various combinations of functionality of the controllers may be included in a single multifunctional controller of the control system 105, as a standalone controller, or in the computing system 150. Additionally, the control and data acquisition circuit 116 is shown as a single logical block for simplicity and may also be considered to include a separate controller circuit and a data and acquisition (DAQ) circuit.

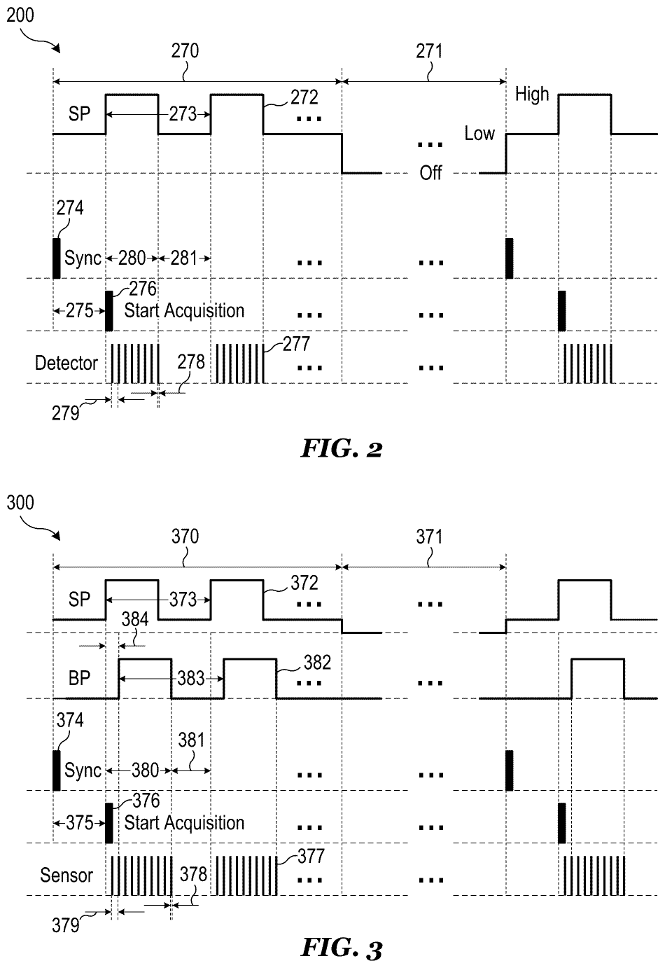

FIG. 2 illustrates an example timing diagram for a sub-millisecond OES detection device configured to acquire OES data from a pulsed plasma OES system that pulses source power during a plasma-on cycle in accordance with embodiments of the invention. The timing diagram of FIG. 2 may be a specific implementation of timing diagrams of OES detection devices described herein, such as the OES detection device of FIG. 1, for example. Similarly labeled elements may be as previously described.

Referring to FIG. 2, a timing diagram 200 for a sub-millisecond OES detection device shows a pulsing strategy for a pulsed plasma process (e.g., a wafer etch, deposition, etc.) and includes a plasma-on cycle 270 and may include an optional plasma-off cycle 271. During the plasma-on cycle 270, source power (e.g., applied to a plasma processing chamber to generate a plasma for use in a pulsed plasma process) is modulated to form SP pulses 272 that alternate between two or more power levels with a SP pulse period 273 (e.g., between a higher SP power value and a lower SP power value that is greater than zero power, as shown, but may also be on-off, such as between an SP power-on value and an SP power-off value, or zero SP power). For example, the SP pulse period 273 may range from about 0.1 ms to about 1 ms, but of course other values are also possible. The SP pulses 272 may be high for a certain percentage of each SP pulse period 273, known as the duty cycle. For example, the duty cycle may be any value between 0% and 100%, such as about 50% (shown here).

That is, the plasma-on cycle 270 refers to the period of time during a pulsed plasma process that includes the SP pulses 272, (i.e. a sequence of SP pulses). In the illustrated example, the plasma-on cycle 270 also refers to the period of time that the SP power is not zero (because the plasma-on cycle 270 alternate between high and low power values). However, in other cases, such as when the SP pulses 272 alternate between SP power-on and SP power-off states, the plasma-on cycle 270 includes periods of time where the SP power is zero. Multiple plasma-on cycles 270 may be separated by optional plasma-off cycles 271 during which no SP power (or very little) is applied to the plasma.

To signal to the OES detection device that it is time to collect OES measurements, a synchronization signal 274 is generated (e.g., by an SP control path configured to generate the SP pulses 272) and sent to the OES detection device. The synchronization signal 274 is related to the timing of the plasma-on cycle 270, the optional plasma-off cycle 271, and/or the individual timing of the SP pulses 272. For example, the synchronization signal 274 may be a signal used by an SP controller to trigger the start of a pulsed plasma cycle (e.g., the start of a first plasma-on cycle, or each plasma-on cycle). The synchronization signal 274 may also be rising or falling edges of the SP pulses 272 themselves (e.g., before amplification).

The OES detection generates a start acquisition signal 276 in response to receiving the synchronization signal 274 that triggers one or more photodetectors to initiate the acquisition of OES data generate. The start acquisition signal 276 may be generated after a setup delay 275 that begins when the OES detection device receives the start acquisition signal 276. In some cases, the setup delay 275 may be used to prepare the photodetector to collect the sequence of OES measurements, such as by setting parameters, selecting a wavelength, or waiting for a specific moment to collect OES measurements. For example, The setup delay 275 may include a survey scan per sensor, setting positions of adjustable wavelength filters to a desired wavelength, and so on.

The photodetector collects a series of optical signal samples 277 in response to the start acquisition signal 276. For example, each optical signal sample 277 has a sample width 278 (integration time), settable in the range of about 100 ns to about 1 ms, for example. The series of OES measurements collected using the optical signal sample 277, also has a sample period 279, which may or may not be the same as the sample width 278 (integration time). The process of the OES detection device triggering off of the plasma processing apparatus (e.g., a plasma tool) so that desired portion(s) of the plasma-on cycle 270, optional plasma-off cycle 271, or the SP pulses 272 themselves are measured for each cycle may be referred to as “strobing” the photodetector. That is, when the detection (e.g., the photodetector) is turned on (e.g., for desired portions of the pulsed plasma process) may be referred to as a strobe-on cycle 280, while a strobe-off cycle 281 may be refer to when detection is turned off. The strobe-off cycle 281 is optional.

In various embodiments, the OES detection device is configured to measure desired portions (shown as when the SP power is high in this case, but can be any desired window) of all cycles (e.g., with frequency in the range of about 1 kHz to about 10 kHz) of a pulsed plasma process through synchronization using the synchronization signal 274 until a process signature (ion, radical, neutral species, etc.) for reactants is detected indicating a change in the pulsed plasma process (e.g. an intermediate point or endpoint). The OES detection device may then indicate to the plasma processing apparatus that the process signature was detected. The benefit to time-resolving this behavior is quite evident in improving the sensitivity to EPD detection, such as by increasing the slope, such as by 2×, or higher, to increase the EPD resolution due to a sharper slope. That is, the slope is not washed out by averaging sample windows over entire on-off cycles. Rather, the active species are specifically integrated without unnecessary background using synchrony with pulses during each cycle.

FIG. 3 illustrates another example timing diagram for a sub-millisecond OES detection device configured to acquire OES data from a pulsed plasma OES system that pulses both source power and bias power during a plasma-on cycle in accordance with embodiments of the invention. The timing diagram of FIG. 3 may be a specific implementation of timing diagrams of OES detection devices described herein, such as the OES detection device of FIG. 1, for example. Similarly labeled elements may be as previously described.

Referring to FIG. 3, a timing diagram 300 for a sub-millisecond OES detection device is similar to the timing diagram 200 including a plasma-on cycle 370 with SP pulses 372 generated with a desired duty cycle during a SP pulse period 373 and with an optional plasma-off cycle 371. In addition to the SP pulses 372, the timing diagram 300 further includes BP pulses 382 (i.e. a sequence of BP pulses) applied with a duty cycle (which may be the same or different than the SP duty cycle) during a BP pulse period 383 (typically the same as the SP pulse period 373). The sequence of BP pulses 382 may be applied with any timing relative to the sequence of SP pulses 372, referred to as a phase shift 384. For example, the phase shift 384 may be any value between 0 and 2π, preferably between 0 and about T.

As with the timing diagram 200, in the timing diagram 300, a synchronization signal 374 is generated and sent to the OES detection device to signal that it is time to collect OES measurements. The synchronization signal 374 may also be related to the individual timing of the BP pulses 382. For example, the desired portions of the cycles may be selected to include certain portions of the BP pulses 382. The example shown is to include the entirety of both the SP pulses 372 and the BP pulses 382, but other windows are possible, such as just the BP pulses 382, or any desired fractions of either the SP pulses 372 or the BP pulses 382. The OES detection generates a start acquisition signal 376 (e.g., after a setup delay 375) and the photodetector collects a series of optical signal samples 377 with sample width 378 and sample period 379 during a strobe on cycle 380 (with an optional strobe off cycle 381) in response to the start acquisition signal 376.

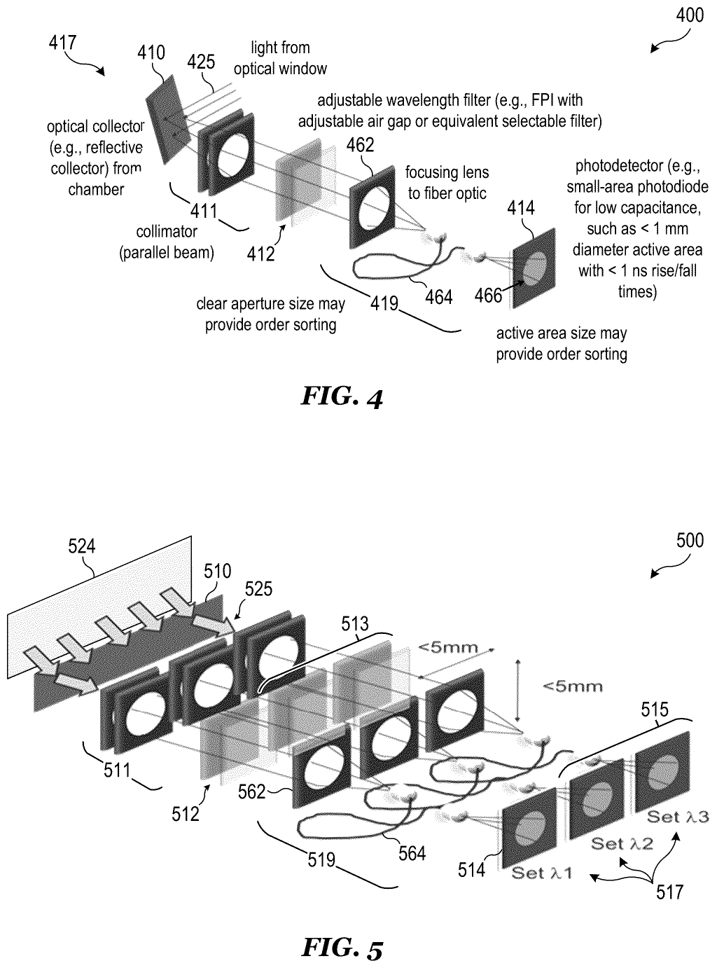

FIG. 4 illustrates example optics of a sub-millisecond OES detection device that includes a single adjustable wavelength optical path where the optical path includes a Fabry-Pérot interferometer (FPI) and a photodiode in accordance with embodiments of the invention. The optics of FIG. 4 may be a specific implementation of optics of OES detection devices described herein, such as the OES detection device of FIG. 1, for example. Similarly labeled elements may be as previously described.

Referring to FIG. 4, optics 400 of an OES detection device include an optical path 417 that includes an optical collector 410 implemented to include at least a reflector (e.g., in cases where the optical signal 425 is received into the optical collector 410 at an angle). In other embodiments, the optical signal 425 is not received at an angle and no reflector is needed. Upstream optics 411 optically couple the optical collector 410 to an adjustable wavelength filter 412 that is implemented as an FPI. In this specific example, the upstream optics 411 include a collimator configured to form a parallel beam from the optical signal 425 and deliver the parallel beam to the adjustable wavelength filter 412.

Downstream optics 419 optically couple the adjustable wavelength filter 412 to a photodetector 414 that is implemented as a photodiode with an active area 466. The downstream optics 419 include a clear aperture 462 and fiber optic 464 in this specific example, but of course more or fewer components may be included. The fiber optic 464 is optically coupled to the photodiode and configured to transmit the filtered optical signal 425 to the photodiode. The clear aperture 462 may be a focusing lens (as shown) that is optically coupled between the adjustable wavelength filter 412 and the fiber optic 426. The focusing lens may be configured to focus the filtered optical signal on an input of the fiber optic.

The optical path 417 is configured to capture/collect plasma light, collimate the light for wavelength selection via a filter, and focus down the filtered light into a fiber optic optically coupled to a small-capacitance photodiode that achieves fast rise/fall times. The adjustable wavelength filter implemented as an FPI (Fabry Pérot interferometer) has a tunable (i.e., adjustable) air gap that can be adjusted at a rate in the preferred range of 1 kHz to 10 kHz (although other rates are of course possible), to a single gap value (defining a single selected wavelength or passband including a range of wavelengths that include the selected wavelength). The tunable air gap is configured to select a (narrow) wavelength of interest for high speed measurement. Additionally, adjustment capability over a large range may enable a survey of the peaks of interest that are available for monitoring for a given plasma process. When this is the case, a multiplicity of desirable passbands having select wavelengths may be found.

During the startup configuration and integration, a measurement gap may be set corresponding to a selected wavelength of interest for detection and monitoring. Focusing the optical signal 425 into the fiber optic 464 may advantageously enable miniaturization of the optical train, and allow separation of the high speed optical sensor from the “hot” windows near the chamber wall. Moreover, as shown in FIG. 5, an array of photodetectors may be installed simultaneously to set and select multiple wavelengths. Or conversely, their multiplicities of response may be used to reconstruct and derive a narrow band through judicious calibration avoiding the slow sweep of many gaps.

Higher orders of the passband may also pass through the adjustable wavelength filter 412. These higher orders may be separated by a distance from one another that may be leveraged for order sorting. For example, the primary peak (i.e., the desired peak) may be in the center and have the least spread (an exit angle near) 0° while the secondary peaks may be off center and exit was small angles relative to the optical path. Or, a physical order sorting filter may be placed in conjunction with the FPI filter, whose product optical transfer function trims off the higher orders. In some embodiments, additional optical components such as clear apertures may be positioned to filter out the higher orders. Because the active area 466 of the photodetector 414 is small, the active area 466 may also be used for order sorting. Consecutive FPIs that are slightly offset may also server an order sorting function. In some embodiments, multiple FPIs may be stacked to achieve an order sorting effect, and additionally, this may include an element that has air in addition to another dielectric film. And, combinations with small optical axis tilts from FPI to FPI may also be used.

FIG. 5 illustrates example optics of a sub-millisecond OES detection device that includes multiple adjustable wavelength optical paths where each optical path includes an FPI and a photodiode in accordance with embodiments of the invention. The optics of FIG. 5 may be a specific implementation of optics of OES detection devices described herein, such as the OES detection device of FIG. 1, for example. Similarly labeled elements may be as previously described.

Referring to FIG. 5, optics 500 of an OES detection device are similar to the optics 400 of FIG. 4 except multiple optical paths 517 are implemented as an array of detectors (an adjustable wavelength filter 512 and a photodetector 514 are included in one optical path while additional adjustable wavelength filters 513 and additional photodetectors 515 are included in respective additional optical paths, such as the 3 total optical paths shown here). Relative to an optical window that might be used for an OES detection device that includes only a single optical path, an elongated optical window 524 may be included in the optics 500 to allow a wider cone of an optical signal 525 to enter an optical collector 510, which is optically coupled to each optical path 517.

Similar to the optical path 417, each optical path 517 includes upstream optics 511 (e.g., a collimator), an adjustable wavelength filter 512 (here implemented as an FPI), downstream optics 519 including a clear aperture 562 and a fiber optic 564, and a photodetector 514 (here implemented as a photodiode). The integration of three or more devices into an array may have the benefit of allowing simultaneous acquisition of OES data relating to multiple chemical species. Furthermore, the small footprint per sensor (e.g., with small-area photodiodes) enables multicolor band monitoring for OES while reducing the space requirement.

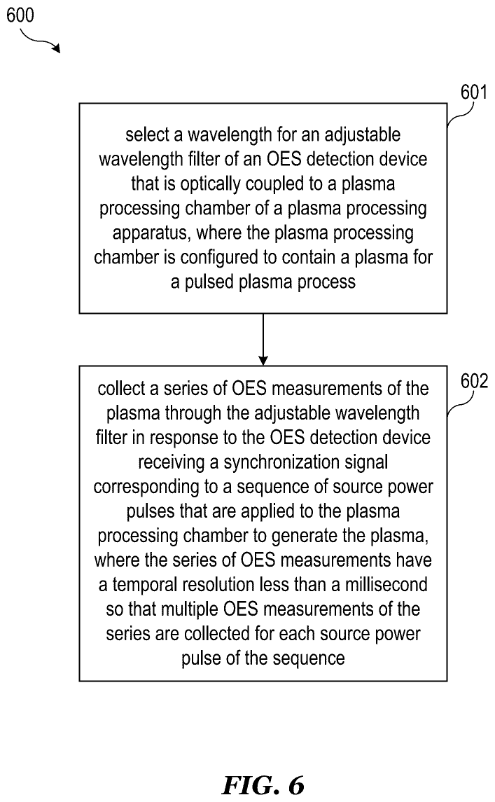

FIG. 6 illustrates a method of collecting OES data of a pulsed plasma process in accordance with embodiments of the invention. The method of FIG. 6 may be combined with other methods and performed using the systems and devices as described herein. For example, the method of FIG. 6 may be combined with any of the embodiments of FIGS. 1-5. Although shown in a logical order, the arrangement and numbering of the steps of FIG. 6 are not intended to be limited. The method steps of FIG. 6 may be performed in any suitable order or concurrently with one another as may be apparent to a person of skill in the art.

Referring to FIG. 6, a method 600 of collecting OES data of a pulsed plasma process includes a step 601 selecting a first wavelength for an adjustable wavelength filter of an OES detection device. The OES detection device is optically coupled to a plasma processing chamber of a plasma processing apparatus. The plasma processing chamber is configured to contain a plasma for the pulsed plasma process. A series of OES measurements of the plasma are collected in a step 602 through the adjustable wavelength filter in response to the OES detection device receiving a synchronization signal corresponding to a sequence of source power pulses applied to the plasma processing chamber to generate the plasma. The series of OES measurements include a temporal resolution less than a millisecond (sub-millisecond) so that multiple OES measurements of the series are collected for each source power pulse of the sequence.

The method 600 may also include synchronizing the series of OES measurements with the sequence of source power pulses by triggering a setup delay in response to receiving the synchronization signal, and starting acquisition of the series of OES measurements after the setup delay. Additionally, the step 602 of collecting the series of OES measurements may be repeated in response to receiving additional synchronization signals where each corresponds to additional sequences of source power pulses. The series of OES measurements may also be monitored for an indication of an endpoint (or intermediate point) of the pulsed plasma process. The plasma processing apparatus may be instructed to terminate (or change) the pulsed plasma process in response to detecting the endpoint (or intermediate point).

The method 600 may further include continuously selecting wavelengths for the adjustable wavelength filter from a range of wavelengths including the first wavelength while collecting the series of OES measurements of the plasma through the adjustable wavelength filter. More than one wavelength may be simultaneously measured. For example, the method 600 may also include selecting a second wavelength for an additional adjustable wavelength filter of the OES detection device. A first series of OES measurements may then be collected at the first wavelength simultaneously with collecting a second series of OES measurements at the second wavelength. Each of the first and second series of OES measurements may then include a temporal resolution less than a millisecond so that multiple OES measurements of each of the first and second series are collected for each source power pulse of the sequence. Collection of the series of OES measurements may also be limited to a selected portion of each power cycle of the sequence of power pulses. The method 600 may then include switching off collection of the series of OES measurements during remaining portions of each source power cycle

Example embodiments of the invention are summarized here. Other embodiments can also be understood from the entirety of the specification as well as the claims filed herein.

Example 1. An OES detection device including: an optical collector configured to be optically coupled to a plasma in a plasma processing apparatus, the optical collector receiving an optical signal from the plasma; an adjustable wavelength filter optically coupled to the optical collector and configured to automatically adjust a passband of the adjustable wavelength filter to include a selected wavelength in response to receiving a wavelength selection signal, and allow a filtered portion of the optical signal to pass through while excluding a remaining portion of the optical signal, the filtered portion including the selected wavelength; and a photodiode optically coupled to the adjustable wavelength filter and configured to generate an electric current as an OES measurement in response to detecting the filtered portion of the optical signal, the photodiode having an active area diameter less than about one millimeter.

Example 2. The OES detection device of example 1, where rise and fall times of the electric current generated by the photodiode are less than about a nanosecond.

Example 3. The OES detection device of one of examples 1 and 2, further including: a timing circuit electrically coupled to the photodiode and configured to generate a setup delay in response to receiving a synchronization signal from the plasma processing apparatus, generate a clock signal having a frequency greater than 1 kHz, cause the OES detection device to collect a series of OES measurements from the photodiode by switching the photodiode off and on after the setup delay according to the clock signal.

Example 4. The OES detection device of one of examples 1 to 3, where the adjustable wavelength filter includes a Fabry-Pérot interferometer with a tunable air gap.

Example 5. The OES detection device of one of examples 1 to 4, further including: a collimator optically coupled between the optical collector and the adjustable wavelength filter, the collimator being configured to form a parallel beam from the optical signal; a fiber optic optically coupled to the photodiode and configured to transmit the filtered optical signal to the photodiode; and a focusing lens optically coupled between the adjustable wavelength filter and the fiber optic, the focusing lens being configured to focus the filtered optical signal on an input of the fiber optic.

Example 6. The OES detection device of one of examples 1 to 5, further including one or more additional optical paths, each including: an additional adjustable wavelength filter optically coupled to the optical collector and configured to automatically adjust a passband of the additional adjustable wavelength filter to include an additional selected wavelength in response to receiving an additional wavelength selection signal, and allow a filtered portion of the optical signal to pass through while excluding a remaining portion of the optical signal, the filtered portion including the additional selected wavelength; and an additional photodiode optically coupled to the adjustable wavelength filter and configured to generate an electric current as an OES measurement in response to detecting the additional filtered portion of the optical signal, the additional photodiode having an active area diameter less than about one millimeter.

Example 7. A pulsed plasma OES system including: a pulsed plasma processing apparatus including a plasma processing chamber, and an SP coupling element configured to generate a plasma contained by the plasma processing chamber; an SP control path electrically coupled to the SP coupling element and configured to supply a sequence of SP pulses to the SP coupling element to generate the plasma; an OES detection device optically coupled to the plasma and including an adjustable wavelength filter and a photodetector; a control and data acquisition circuit electrically coupled to the adjustable wavelength filter and the photodetector, the control and data acquisition circuit being configured to adjust a passband of the adjustable wavelength filter to a selected wavelength using a wavelength selection signal, and cause the photodetector to collect a series of OES measurements of the plasma, the series of OES measurements including a temporal resolution less than a millisecond so that multiple OES measurements of the series are collected for each SP pulse of the sequence.

Example 8. The pulsed plasma OES system of example 7, where the control and data acquisition circuit is further configured to set an integration time of the photodetector to between about 2 microseconds and about 100 microseconds.

Example 9. The pulsed plasma OES system of one of examples 7 and 8, further including: a timing circuit electrically coupled to the control and data acquisition circuit, the timing circuit being configured to generate a clock signal having a frequency greater than 1 kHz in response to receiving a synchronization signal corresponding to the sequence of SP pulses; and where the control and data acquisition circuit is further configured to cause the OES detection device to collect the series of OES measurements using the photodetector by switching the photodetector off and on after the setup delay according to the clock signal.

Example 10. The pulsed plasma OES system of example 9, where the control and data acquisition circuit is further configured to use the synchronization signal to cause the OES detection device to collect the series of OES measurements during a selected portion of each power cycle of the sequence of SP pulses.

Example 11. The pulsed plasma OES system of one of examples 9 and 10, further including: a bias power (BP) control path configured to supply a sequence of BP pulses to a substrate holder of the pulsed plasma processing apparatus disposed within the plasma processing chamber and configured to support a substrate; where the control and data acquisition circuit is further configured to use the synchronization signal to cause the OES detection device to collect the series of OES measurements during a selected portion of each power cycle of the sequence of BP pulses.

Example 12. The pulsed plasma OES system of example 7, further including: a bias power (BP) control path configured to supply a sequence of BP pulses to a substrate holder of the pulsed plasma processing apparatus disposed within the plasma processing chamber and configured to support a substrate; a timing circuit electrically coupled to the control and data acquisition circuit, the timing circuit being configured to trigger the control and data acquisition circuit to cause the photodetector to collect the series of OES measurements in response to receiving a synchronization signal from at least one of the SP control path and the BP control path; where the control and data acquisition circuit is further configured to process, amplify, and digitize the series of OES measurements for output to a computing system.

Example 13. The pulsed plasma OES system of one of examples 7 to 12, where the adjustable wavelength filter is a Fabry-Pérot interferometer with a tunable air gap, and where the photodetector is a photodiode having an active area diameter less than about one millimeter.

Example 14. A method of collecting OES data of a pulsed plasma process, the method including: selecting a first wavelength for an adjustable wavelength filter of an OES detection device optically coupled to a plasma processing chamber of a plasma processing apparatus, the plasma processing chamber being configured to contain a plasma for the pulsed plasma process; and collecting a series of OES measurements of the plasma through the adjustable wavelength filter in response to the OES detection device receiving a synchronization signal corresponding to a sequence of source power pulses applied to the plasma processing chamber to generate the plasma, the series of OES measurements including a temporal resolution less than a millisecond so that multiple OES measurements of the series are collected for each source power pulse of the sequence.

Example 15. The method of example 14, further including: receiving the synchronization signal from a controller configured to control the application of the sequence of source power pulses to the plasma processing apparatus; synchronizing the series of OES measurements with the sequence of source power pulses by triggering a setup delay in response to receiving the synchronization signal; and starting acquisition of the series of OES measurements after the setup delay.

Example 16. The method of one of examples 14 and 15, further including: repeating the step of collecting the series of OES measurements from the plasma in response to receiving additional synchronization signals, each corresponding to additional sequences of source power pulses.

Example 17. The method of one of examples 14 to 16, further including: continuously selecting wavelengths for the adjustable wavelength filter from a range of wavelengths including the first wavelength while collecting the series of OES measurements of the plasma through the adjustable wavelength filter.

Example 18. The method of one of examples 14 to 17, further including: monitoring the series of OES measurements for an indication of an endpoint of the pulsed plasma process; and instructing the plasma processing apparatus to terminate the pulsed plasma process in response to detecting the endpoint.

Example 19. The method of one of examples 14 to 18, further including: selecting a second wavelength for an additional adjustable wavelength filter of the OES detection device; and where collecting the series of OES measurements of the plasma includes simultaneously collecting a first series of OES measurements at the first wavelength and collecting a second series of OES measurements at the second wavelength, each of the first and second series of OES measurements including a temporal resolution less than a millisecond so that multiple OES measurements of each of the first and second series are collected for each source power pulse of the sequence.

Example 20. The method of one of examples 14 to 19, where collecting the series of OES measurements of the plasma includes: collecting the series of OES measurements during a selected portion of each power cycle of the sequence of source power pulses; and switching off collection of the series of OES measurements during remaining portions of each power cycle.

Example 21. The method of example 20, where collecting the series of OES measurements of the plasma further includes: collecting the series of OES measurements during a selected portion of each wafer bias “on” power cycle applied during each power cycle of the sequence, where wafer bias pulses corresponding with each wafer bias “on” power cycle are in synchrony or out of synchrony with source power pulses of each power cycle; and switching off collection of the series of OES measurements during remaining portions of each power cycle including each wafer bias “off” power cycle.

Example 22. The method of example 21, where collecting the series of OES measurements of the plasma includes: collecting the series of OES measurements utilizing light collection through a gimbal; and reporting, in real-time, the difference between OES measurements from the center of the substrate and OES measurement from edges of the substrate.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. An optical emission spectroscopy (OES) detection device comprising:
an optical collector configured to be optically coupled to a plasma in a plasma processing apparatus, the optical collector receiving an optical signal from the plasma;
an adjustable wavelength filter optically coupled to the optical collector and configured to
automatically adjust a passband of the adjustable wavelength filter to include a selected wavelength in response to receiving a wavelength selection signal, and
allow a filtered portion of the optical signal to pass through while excluding a remaining portion of the optical signal, the filtered portion comprising the selected wavelength; and
a photodiode optically coupled to the adjustable wavelength filter and configured to generate an electric current as an OES measurement in response to detecting the filtered portion of the optical signal, the photodiode having an active area diameter less than about one millimeter.

2. The OES detection device of claim 1, wherein rise and fall times of the electric current generated by the photodiode are less than about a nanosecond.

3. The OES detection device of claim 1, further comprising:
a timing circuit electrically coupled to the photodiode and configured to
generate a setup delay in response to receiving a synchronization signal from the plasma processing apparatus,
generate a clock signal having a frequency greater than 1 kHz,
cause the OES detection device to collect a series of OES measurements from the photodiode by switching the photodiode off and on after the setup delay according to the clock signal.

4. The OES detection device of claim 1, wherein the adjustable wavelength filter comprises a Fabry-Pérot interferometer with a tunable air gap.

5. The OES detection device of claim 1, further comprising:
a collimator optically coupled between the optical collector and the adjustable wavelength filter, the collimator being configured to form a parallel beam from the optical signal;
a fiber optic optically coupled to the photodiode and configured to transmit the filtered optical signal to the photodiode; and
a focusing lens optically coupled between the adjustable wavelength filter and the fiber optic, the focusing lens being configured to focus the filtered optical signal on an input of the fiber optic.

6. The OES detection device of claim 1, further comprising one or more additional optical paths, each comprising:
an additional adjustable wavelength filter optically coupled to the optical collector and configured to
automatically adjust a passband of the additional adjustable wavelength filter to include an additional selected wavelength in response to receiving an additional wavelength selection signal, and
allow a filtered portion of the optical signal to pass through while excluding a remaining portion of the optical signal, the filtered portion comprising the additional selected wavelength; and
an additional photodiode optically coupled to the adjustable wavelength filter and configured to generate an electric current as an OES measurement in response to detecting the additional filtered portion of the optical signal, the additional photodiode having an active area diameter less than about one millimeter.

7. A pulsed plasma optical emission spectroscopy (OES) system comprising:
a pulsed plasma processing apparatus comprising
a plasma processing chamber, and
a source power (SP) coupling element configured to generate a plasma contained by the plasma processing chamber;
an SP control path electrically coupled to the SP coupling element and configured to supply a sequence of SP pulses to the SP coupling element to generate the plasma;
an OES detection device optically coupled to the plasma and comprising an adjustable wavelength filter and a photodetector;
a control and data acquisition circuit electrically coupled to the adjustable wavelength filter and the photodetector, the control and data acquisition circuit being configured to
adjust a passband of the adjustable wavelength filter to a selected wavelength using a wavelength selection signal, and
cause the photodetector to collect a series of OES measurements of the plasma, the series of OES measurements comprising a temporal resolution less than a millisecond so that multiple OES measurements of the series are collected for each SP pulse of the sequence.

8. The pulsed plasma OES system of claim 7, wherein the control and data acquisition circuit is further configured to set an integration time of the photodetector to between about 2 microseconds and about 100 microseconds.

9. The pulsed plasma OES system of claim 7, further comprising:
a timing circuit electrically coupled to the control and data acquisition circuit, the timing circuit being configured to generate a clock signal having a frequency greater than 1 kHz in response to receiving a synchronization signal corresponding to the sequence of SP pulses; and
wherein the control and data acquisition circuit is further configured to cause the OES detection device to collect the series of OES measurements using the photodetector by switching the photodetector off and on after the setup delay according to the clock signal.

10. The pulsed plasma OES system of claim 9, wherein the control and data acquisition circuit is further configured to use the synchronization signal to cause the OES detection device to collect the series of OES measurements during a selected portion of each power cycle of the sequence of SP pulses.

11. The pulsed plasma OES system of claim 9, further comprising:
a bias power (BP) control path configured to supply a sequence of BP pulses to a substrate holder of the pulsed plasma processing apparatus disposed within the plasma processing chamber and configured to support a substrate;
wherein the control and data acquisition circuit is further configured to use the synchronization signal to cause the OES detection device to collect the series of OES measurements during a selected portion of each power cycle of the sequence of BP pulses.

12. The pulsed plasma OES system of claim 7, further comprising:
a bias power (BP) control path configured to supply a sequence of BP pulses to a substrate holder of the pulsed plasma processing apparatus disposed within the plasma processing chamber and configured to support a substrate;
a timing circuit electrically coupled to the control and data acquisition circuit, the timing circuit being configured to trigger the control and data acquisition circuit to cause the photodetector to collect the series of OES measurements in response to receiving a synchronization signal from at least one of the SP control path and the BP control path;
wherein the control and data acquisition circuit is further configured to process, amplify, and digitize the series of OES measurements for output to a computing system.

13. The pulsed plasma OES system of claim 7, wherein the adjustable wavelength filter is a Fabry-Pérot interferometer with a tunable air gap, and wherein the photodetector is a photodiode having an active area diameter less than about one millimeter.

14. A method of collecting optical emission spectroscopy (OES) data of a pulsed plasma process, the method comprising:
selecting a first wavelength for an adjustable wavelength filter of an OES detection device optically coupled to a plasma processing chamber of a plasma processing apparatus, the plasma processing chamber being configured to contain a plasma for the pulsed plasma process; and
collecting a series of OES measurements of the plasma through the adjustable wavelength filter in response to the OES detection device receiving a synchronization signal corresponding to a sequence of source power pulses applied to the plasma processing chamber to generate the plasma, the series of OES measurements comprising a temporal resolution less than a millisecond so that multiple OES measurements of the series are collected for each source power pulse of the sequence.

15. The method of claim 14, further comprising:
receiving the synchronization signal from a controller configured to control the application of the sequence of source power pulses to the plasma processing apparatus;
synchronizing the series of OES measurements with the sequence of source power pulses by triggering a setup delay in response to receiving the synchronization signal; and
starting acquisition of the series of OES measurements after the setup delay.

16. The method of claim 14, further comprising:
repeating the step of collecting the series of OES measurements from the plasma in response to receiving additional synchronization signals, each corresponding to additional sequences of source power pulses.

17. The method of claim 14, further comprising:
continuously selecting wavelengths for the adjustable wavelength filter from a range of wavelengths including the first wavelength while collecting the series of OES measurements of the plasma through the adjustable wavelength filter.

18. The method of claim 14, further comprising:
monitoring the series of OES measurements for an indication of an endpoint of the pulsed plasma process; and
instructing the plasma processing apparatus to terminate the pulsed plasma process in response to detecting the endpoint.

19. The method of claim 14, further comprising:
selecting a second wavelength for an additional adjustable wavelength filter of the OES detection device; and
wherein collecting the series of OES measurements of the plasma comprises simultaneously collecting a first series of OES measurements at the first wavelength and collecting a second series of OES measurements at the second wavelength, each of the first and second series of OES measurements comprising a temporal resolution less than a millisecond so that multiple OES measurements of each of the first and second series are collected for each source power pulse of the sequence.

20. The method of claim 14, wherein collecting the series of OES measurements of the plasma comprises:
collecting the series of OES measurements during a selected portion of each power cycle of the sequence of source power pulses; and
switching off collection of the series of OES measurements during remaining portions of each power cycle.

21. The method of claim 20, wherein collecting the series of OES measurements of the plasma further comprises:
collecting the series of OES measurements during a selected portion of each wafer bias “on” power cycle applied during each power cycle of the sequence, wherein wafer bias pulses corresponding with each wafer bias “on” power cycle are in synchrony or out of synchrony with source power pulses of each power cycle; and
switching off collection of the series of OES measurements during remaining portions of each power cycle including each wafer bias “off” power cycle.

22. The method of claim 21, wherein collecting the series of OES measurements of the plasma comprises:
collecting the series of OES measurements utilizing light collection through a gimbal; and
reporting, in real-time, the difference between OES measurements from the center of the substrate and OES measurement from edges of the substrate.
